(19) United States
(12) Patent Application Publication
(10) Pub. No.: US 2004/0059977 A1
(43) Pub. Date: Mar. 25, 2004

(54) Method of processing test patterns for an integrated circuit

(76) Inventor: Chee Hong Liau, Munchen (DE)

Correspondence Address: LERNER AND GREENBERG, P.A., POST OFFICE BOX 2480, HOLLYWOOD, FL, 33022-2480, US

(21) Appl. No.: 10/622,933

(22) Filed: Jul. 18, 2003

(30) Foreign Application Priority Data
Jul. 19, 2002 (EP) 02 090 272.2

(51) Int. Cl. G06F 11/00; G01R 31/28

(52) U.S. Cl. 714/741

(57) ABSTRACT

A method of approximating the behavior of an integrated circuit includes applying a set of test patterns to a system for testing or simulating an integrated circuit, applying the set of test patterns to a neural network, comparing the outputs of the system for testing or simulating the integrated circuit and the outputs of the neural network, and adapting parameters of the neural network to approximate the behavior of the integrated circuit on the basis of the comparison. The dynamic behavior of the integrated circuit device can be learned from a set of random test patterns using a neural network. After the learning process has been completed, the automatic test equipment is able to perform a test pattern classification. The automatic test equipment may thus select test patterns for a subsequent simulation or testing of the integrated circuit. The selected patterns can be further optimized using a genetic algorithm.

### BACKGROUND OF THE INVENTION

1. Field of the Invention

To achieve high performance and high integration density, the dimensions of integrated circuit components are scaled down more and more. In particular, transistor dimensions are scaled down while lower power dissipation is achieved by scaling down the supply voltage. However, due to high packing density of transistors, the power supply current is increasing, and hence, large current swings within a short period of time can cause considerable noise. As a consequence, one difficulty circuit designers face is the power delivery of very high performance circuits due to the severe switching noise.

In order to verify the function of a newly designed integrated circuit, the circuit is first simulated and then tested. During simulation, multiple input signals are applied to the inputs of the circuit, and the output signals of the circuit calculated. The input signals are referred to as test patterns. If the output signals do not sufficiently approximate preset target signals, the circuit is redesigned and re-simulated.

Subsequently, when simulation is completed, a chip containing the integrated circuit is manufactured and tested using ATE (Automatic Test Equipment). The ATE also applies a test pattern to the circuit. The test pattern for the ATE has to be input manually by a user. Generally, the same test pattern that has been used for simulation is also used for testing. If the output signals generated by the circuit in response to the test pattern of the ATE deviate from preset target signals, the circuit is redesigned, re-simulated and retested.

As the complexity of integrated circuits increases, integration density and functionality increases dramatically. The simultaneous switching of a large number of transistors induces a large current spike. The switching noise on the power distribution network must be suppressed to a tolerable level to ensure the reliability of the circuit. In order to efficiently combat the switching noise, estimation of the worst case switching noise is required.

On way of determining the worst case switching noise is to simulate all combinations of input patterns to determine which combination will induce the maximum switching noise. However, the complexity of the solution space is exponentially proportional to the number of primary inputs of the system. Accordingly, it would require an enormous time to process the entire solution space for even a moderately complex system.

As a consequence, it is almost impossible to determine all test patterns that cause worst case switching noise by simulation or testing. Accordingly, a small set of test patterns that cause at least some worst case scenarios can be selected. However, this way, the simulation or testing of the integrated circuit may not be satisfactory.

The designer thus has to accept either enormous time requirements for simulation and testing, or potentially insufficient simulation or testing efficiency. This is clearly undesirable.

To this end, some approaches have been proposed to deal with these problems. In “Estimation of Switching Noise on Power Supply Lines in Deep Sub-micron CMOS circuits”, Shiyou Zhao and Kaushik Roy, 13^{th} International Conference on VLSI Design, IEEE January 2000, there is proposed a probabalistic approach to determine the lower bound of the worst case switching noise on power supply lines. The algorithm described therein traces the worst case input patterns which induces the steepest maximum switching current spike and therefore the maximum switching noise. This is based on the observation that the maximum switching noise is directly related to the steepest maximum switching current spike.

In this approach, the design of an integrated circuit is simulated by applying randomly generated input signal vectors to the inputs of the circuit. For each input vector pair, the simulated peak switching current is determined. The worst case input vector pairs feed, as initial population, a genetic algorithm. The genetic algorithm is designed to single out the near optimal input pattern(s) that induce the steepest maximum switching current spike and, therefore, the worst case switching noise. The worst case input patterns are then used in HSPICE (simulation program with integrated circuit emphasis) simulation of the circuits to extract the exact current waveform.

One problem associated with this approach is the difficulty of generating suitable random test patterns. The larger the number of random test patterns, the higher the likelihood of generating a test pattern which approximates the worst case sufficiently. However, since the simulation of each test pattern is time consuming, the simulation of a large number of test patterns is not practical.

In particular, if a genetic algorithm is used, it is too time consuming to simulate every single random pattern out of every new pattern population before the algorithm is able to determine which of the patterns of the population is to be selected for further optimization. Therefore, this method becomes saturated by the number of trial random patterns in each pattern population. It is suitable for small circuits. However, it could take up to years to perform a full chip simulation of a large circuit using even the fastest simulation applications.

### SUMMARY OF THE INVENTION

It is accordingly an object of the invention to provide a method of approximating a behavior of an integrated circuit, a method of selecting test patterns, a method of simulating an integrated circuit, a method of testing an integrated circuit, a method of providing a test pattern for a simulation or a test of a layout of an integrated circuit, a data processing configuration, and a computer-readable medium having computer-executable instructions for performing a method approximating a behavior of an integrated circuit which overcome the above-mentioned disadvantages of the heretofore-known methods and devices of this general type.

With the foregoing and other objects in view there is provided, in accordance with the invention, a method of approximating the behavior of an integrated circuit including the steps of:

(a) applying a set of test patterns to a system for testing or simulating an integrated circuit;

(b) applying the set of test patterns to a neural network;

(c) comparing outputs of the system for testing or simulating the integrated circuit and outputs of the neural network for providing a comparison result; and

(d) adapting parameters of the neural network to approximate a behavior of the integrated circuit based the comparison result.

In particular, the system for testing or simulating the integrated circuit may be an automatic test equipment (ATE), and the set of test patterns is applied to the integrated circuit via the automatic test equipment. The neural network may be integrated in the ATE. It may be implemented using any known ATE.

The invention is based on the idea that the dynamic behavior of the integrated circuit device can be learnt from a set of random test patterns using a neural network.

This mode of operation of the neural network can be referred to as learning mode.

After the learning process has been completed, the ATE is able to perform test pattern classification. The ATE may thus select sub-optimal patterns for subsequent simulation or testing of the integrated circuit. The selected test patterns sufficiently approximate worst case scenarios.

Another mode of the invention includes implementing the neural network in the automatic test equipment.

Yet another mode of the invention includes generating the set of test patterns on a random basis.

According to a another mode of the invention, step (d) includes adapting inter-unit weights of the neural network through back-propagation.

Yet another mode of the invention includes repeating steps (a) to (d) until a level of adaptation in step (d) falls below a given value.

A further mode of the invention includes storing data representing predetermined neural network parameters after terminating a repetition of steps (a) to (d).

With the objects of the invention in view there is also provided, a method of selecting test patterns, the method includes the steps of:

(a) approximating a behavior of an integrated circuit by applying a set of test patterns to a system for testing or simulating the integrated circuit, applying the set of test patterns to a neural network, comparing outputs of the system for one testing and simulating the integrated circuit and outputs of the neural network for providing a comparison result, and adapting parameters of the neural network in order to approximate the behavior of the integrated circuit based the comparison result;

(b) applying a test pattern to the neural network whose parameters have been adapted to approximate the behavior of the integrated circuit in accordance with step (a);

(c) processing an output of the neural network to determine whether given criteria are met; and

(d) selecting the test pattern for storage if the given criteria are met.

In other words, the invention also provides for a method of selecting test patterns, the method including the steps of:

(a) applying a test pattern to a neural network whose parameters have been adapted to approximate the behavior of an integrated circuit according to the above described method;

(b) processing the output of the neural network to determine whether predetermined criteria are met; and

(c) selecting for storage the test pattern if the predetermined criteria are met.

Using this method, a sufficient number of test patterns are provided for an efficient simulation or testing of the integrated circuit.

This mode of operation of the neural network can be referred to as operation mode.

A further mode of the invention includes repeating steps (b) to (d) until a given number of test patterns have been stored.

Another mode of the invention includes concluding that the given criteria are met if a value of a given parameter of a signal output by the neural network in response to applying the test pattern exceeds a reference value.

A further mode of the invention includes the steps of:

(e) applying a further set of test patterns to the integrated circuit by using an automatic test equipment;

(f) measuring values of the given parameter of output signals generated by the integrated circuit in response to step (e); and

(g) concluding that the given criteria are met if the value of the given parameter of the signal output by the neural network in response to applying a test pattern exceeds the reference value and all values measured in step (f).

A further mode of the invention includes the step of generating the further set of test patterns on a random basis.

A further mode of the invention includes the step of using a dynamic current as the given parameter.

A further mode of the invention includes the steps of:

(h) generating a test pattern population formed of a plurality of test patterns;

(i) applying each test pattern of the test pattern population to the neural network;

(j) processing, for each test pattern, the output of the neural network to determine a value of a given parameter; and

(k) allocating each test pattern to one of a plurality of classification groups in accordance with the value of the given parameter determined in step (j).

A further mode of the invention includes repeating steps (h) to (k) using a new test pattern population formed of test patterns included in a selected one of the classification groups.

A further mode of the invention includes the step of using, as the selected one of the classification groups, test patterns that approximate a set of worst case input parameters of operation of the integrated circuit.

Another mode of the invention includes repeating steps (b) to (d) a number of times; applying the test patterns selected in each step (d) to a simulator for simulating the integrated circuit; processing an output of the simulator to determine whether further given criteria are met; and selecting for storage those test patterns that meet the further given criteria.

A further mode of the invention includes repeating steps (b) to (d) a number of times; applying test patterns selected in each repetition of step (d) to the integrated circuit by using an automatic test equipment; processing an output of the automatic test equipment to determine whether further given criteria are met; and selecting for storage those test patterns which meet the further given criteria.

A further mode of the invention includes the step of using, as the given criteria, a representation of an approximation of a worst case mode of operation of the integrated circuit.

With the objects of the invention in view there is also provided, a method of simulating an integrated circuit, the method includes the steps of:

selecting test patterns by, in a first step, applying a test pattern to a neural network whose parameters have been adapted to approximate a behavior of an integrated circuit by applying a set of test patterns to a system for testing or simulating the integrated circuit, applying the set of test patterns to a neural network, and comparing outputs of the system for testing or simulating the integrated circuit and outputs of the neural network, and, in a second step, processing an output of the neural network to determine whether given criteria are met and selecting a test pattern if the given criteria are met; and

applying test patterns that have been selected to a simulator for simulating the integrated circuit.

More generally, there is provided a method of simulating an integrated circuit, the method including the steps of applying test patterns that have been selected according to the above described method of selecting test patterns to a simulator for simulating an integrated circuit.

With the objects of the invention in view there is also provided, a method of testing an integrated circuit, the method including the steps of:

selecting test patterns by, in a first step, applying a test pattern to a neural network whose parameters have been adapted to approximate a behavior of an integrated circuit by applying a set of test patterns to a system for testing or simulating the integrated circuit, applying the set of test patterns to a neural network, and comparing outputs of the system for testing or simulating the integrated circuit and outputs of the neural network, and, in a second step, processing an output of the neural network to determine whether given criteria are met and selecting a test pattern if the given criteria are met; and

applying test patterns that have been selected to the integrated circuit by using an automatic test equipment.

Accordingly, there is also provided a method of testing an integrated circuit, the method including the steps of applying test patterns that have been selected according to the above described method of selecting test patterns to the integrated circuit using automatic test equipment (ATE).

According to a preferred embodiment of the invention, the test patterns that have been selected in accordance with the above described neural network-based approach are further optimized using a genetic algorithm.

With the objects of the invention in view there is also provided, a method of providing a test pattern for one of a simulation and a test of a layout of an integrated circuit, the method includes the steps of:

(A) providing a set of test patterns that have been selected by, in a first step, applying a test pattern to a neural network whose parameters have been adapted to approximate a behavior of an integrated circuit by applying a set of test patterns to a system for testing or simulating an integrated circuit, applying the set of test patterns to a neural network, and comparing outputs of the system for testing or simulating the integrated circuit and outputs of the neural network, and, in a second step, processing an output of the neural network to determine whether given criteria are met and selecting a test pattern if the given criteria are met; and

(B) applying the set of test patterns to the integrated circuit by using an automatic test equipment (ATE);

(C) determining outputs of the integrated circuit;

(D) processing the outputs to determine whether given test criteria are met; and

(E) depending on a determination in step (D), generating a new set of test patterns based on the set of test patterns provided by step (A) by using a genetic algorithm.

In other words, there is provided a method of providing a test pattern for the simulation and/or test of the layout of an integrated circuit, the method including the steps of:

providing a set of test patterns consisting of test patterns selected in accordance with the above described method of selecting test patterns;

applying the set of test patterns to the integrated circuit using automatic test equipment (ATE);

determining the outputs of the integrated circuit;

processing the outputs to determine whether predetermined test criteria are met; and

depending on the determination in the processing step, generating a new set of test patterns on the basis of the set of test patterns provided by the step of providing the set of test patterns using a genetic algorithm.

This combination of neural network- and genetic algorithm-based approaches further increases the chances of finding test patterns that sufficiently approximate worst case scenarios of operation of the integrated circuit.

The method employs a genetic algorithm (optimization method) to optimize a set of pre-selected patterns based on measurements using an ATE. Thereby, a set of worst case noise patterns can be selected automatically. By using ATE for the processing of the test patterns, performance is greatly enhanced compared to approaches based on simulation.

Test patterns generated accordingly can additionally be re-simulated for further detail design analysis and improvement.

The genetic algorithm approach can be implemented using existing ATEs.

A further mode of the method according to the invention includes repeating steps (B) to (E) until the given test criteria are met.

A further mode of the method according to the invention includes repeating steps (B) to (E) until the given test criteria are met or repeating steps (B) to (E) a given number of times.

A further mode of the method according to the invention includes the step of concluding that the given test criteria are met if the set of test patterns is associated with an average fitness above a given value.

According to another mode of the invention step (E) includes combining some or all of the test patterns according to the genetic algorithm in order to provide the new set of test patterns.

A further mode of the method according to the invention includes the step of selecting test patterns from the set of test patterns according to given selection criteria in order to provide selected test patterns; and combining the selected test patterns according to the genetic algorithm to provide the new set of test patterns.

A further mode of the method according to the invention includes the step of selecting a test pattern if the test pattern is associated with a fitness value greater than a reference value.

A further mode of the method according to the invention includes the step of selecting a test pattern if the test pattern is associated with a highest fitness value of all unselected test patterns.

Another mode of the method according to the invention includes the step of selecting a test pattern if the test pattern is associated with a highest fitness value of all unselected test patterns, and repeating the selecting step until a given percentage of test patterns has been selected.

According to another mode of the invention step (E) includes:

(F) sorting selected test patterns according to an order of associated fitness values;

(G) randomly selecting parent test patterns from test patterns as sorted in step (F); and

(H) combining selected ones of the parent test patterns.

A further mode of the method according to the invention includes the step of using a mutation, a crossing over, and/or a re-combination for the genetic algorithm.

According to another mode of the invention the step (A) includes providing a plurality of sets of test patterns such that each of the sets of test patterns is included in a test pattern population.

A further mode of the method according to the invention includes the step of providing a plurality of test pattern populations and performing steps (B) to (E) for each of the test pattern populations.

With the objects of the invention in view there is also provided, a data processing configuration, including:

a system for testing or simulating an integrated circuit, said system being configured to be supplied with a set of test patterns;

a neural network operatively connected to said system for testing or simulating the integrated circuit, said neural network being configured to be provided with the set of test patterns;

a comparison unit operatively connected to said neural network and said system for testing or simulating the integrated circuit, said comparison unit being configured to compare outputs from said system for testing or simulating the integrated circuit and from said neural network in order to provide a comparison result; and

an adapting unit operatively connected to said comparison unit, said adapting unit being configured to adapt parameters of said neural network in order to approximate a behavior of the integrated circuit based the comparison result.

With the objects of the invention in view there is also provided, a computer-readable medium having computer-executable instructions for performing a method which includes the steps of:

applying a set of test patterns to a system for testing or simulating an integrated circuit;

applying the set of test patterns to a neural network;

comparing outputs of the system for testing or simulating the integrated circuit and outputs of the neural network for providing a comparison result; and

adapting parameters of the neural network to approximate a behavior of the integrated circuit based the comparison result.

More generally, according to the invention, there is provided a computer program for performing any of the methods according to the invention and a data processing system, adapted to perform any of the methods according to the invention.

Other features which are considered as characteristic for the invention are set forth in the appended claims.

Although the invention is illustrated and described herein as embodied in method of processing test patterns for an integrated circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic illustration of a classification of three groups of test patterns;

FIG. 2 is a flow chart illustrating a process representing the neural network learning mode according to an embodiment of the invention;

FIG. 3 is a flow chart illustrating a process representing the neural network operation mode according to an embodiment of the invention;

FIG. 4 is a schematic flow chart of a genetic algorithm using an initial random pattern generation according to the invention; and

FIG. 5 is a flow chart illustrating a method combining a neural network-based pre-selection of test patterns and a subsequent optimization using a genetic algorithm according to the invention.

### DESCRIPTION OF THE PREFERRED EMBODIMENTS

In accordance with one embodiment of the invention, a neural network model is implemented into the ATE. That is, the ATE is able to learn automatically from test runs of an integrated circuit performed on the ATE. After training of the neural network has been completed, it is able to identify which group of test patterns belong to a sub-optimal set. For this purpose, some million test patterns are selected vie the neural network. Subsequently, the pre-selected sub-optimal pattern is simulated (simulation approach) or measured (ATE approach) to further determine which of the patterns fulfill predetermined criteria. Those patterns which fulfill the criteria are selected for storage.

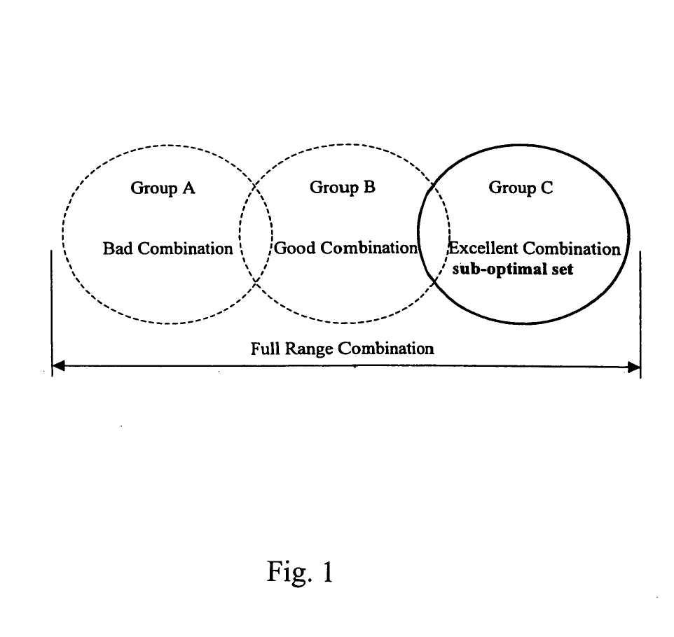

FIG. 1 illustrates schematically a classification of three groups of patterns. Since the simulation approach- or ATE approach-based selection of patterns is performed on the basis of a sub-optimal set of patterns (group C), the speed and efficiency compared to conventional methods for identifying suitable test patterns is considerably improved. This approach is referred to as maximum approximation.

Suppose, as illustrated in FIG. 1, there are P_{N}∈{P_{N}^{A} P_{N}^{B} P_{N}^{C}}, N>0, three groups of test patterns within a full range of all possible test patterns. Instead of searching through all possible patterns, the neural network may learn and distinguish between different groups of test patterns using an ATE-based training program. Accordingly, the test patterns are pre-classified.

In the maximum approximation algorithm mode, the sub-optimal set P_{N}^{C} and P_{N}^{B}∩P_{N}^{C} are generated based on neural network decisions, and a sub-optimal pattern set forms a new pattern population.

This process can be repeated iteratively on the basis of the new pattern population, thereby to select the best group of patterns out of the sub-optimal population, and so on.

A neural network is an interconnected assembly of simple processing elements, units or nodes, whose functionality is loosely based on that of the animal neuron. The network ability of the network is stored in the inter-unit connection strengths, or weights, obtained by a process of adaptation to, or learning from, a set of training patterns.

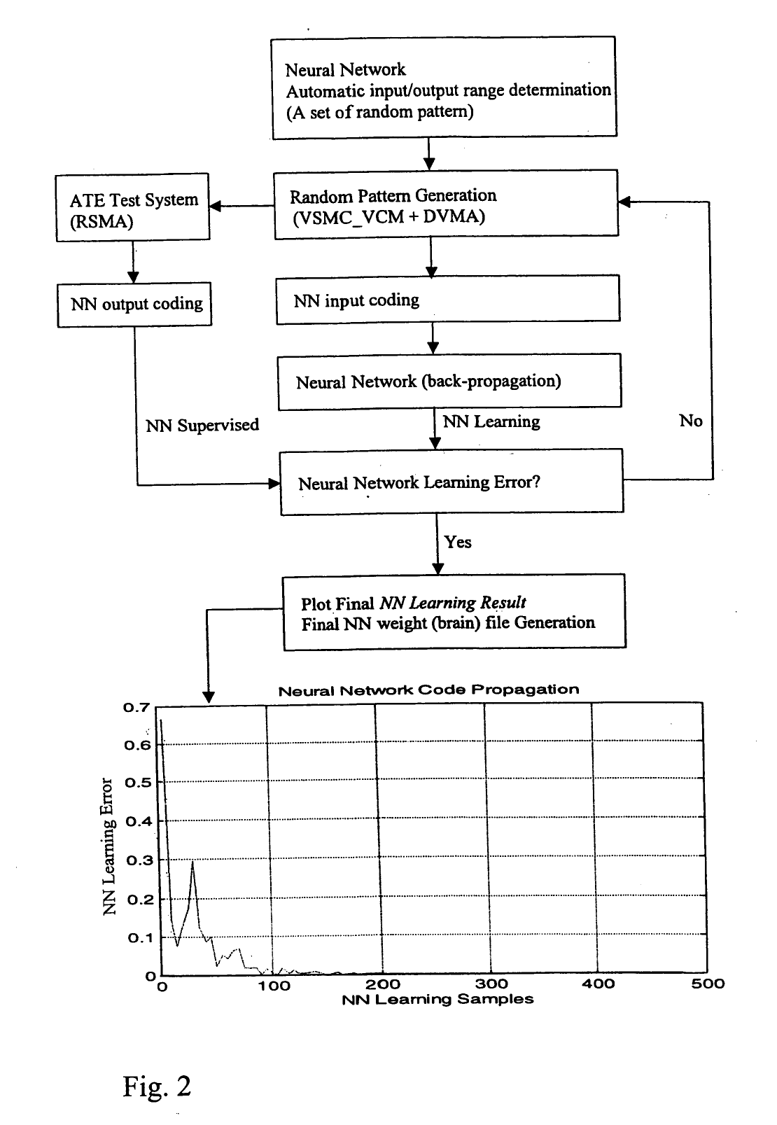

FIG. 2 illustrates a process representing the neural network learning mode according to an embodiment of the invention. The neural network is based on back-propagation net characteristics to perform a pattern classification task. In the beginning, the neural network learns from a set of random patterns. The test results are supervised by a test system (ATE). The learning process is terminated when the learning error is less than a predetermined value. Subsequently, a neural network learning weight (“brain”) file is generated. This file is then used in operation mode to perform a pattern classification task.

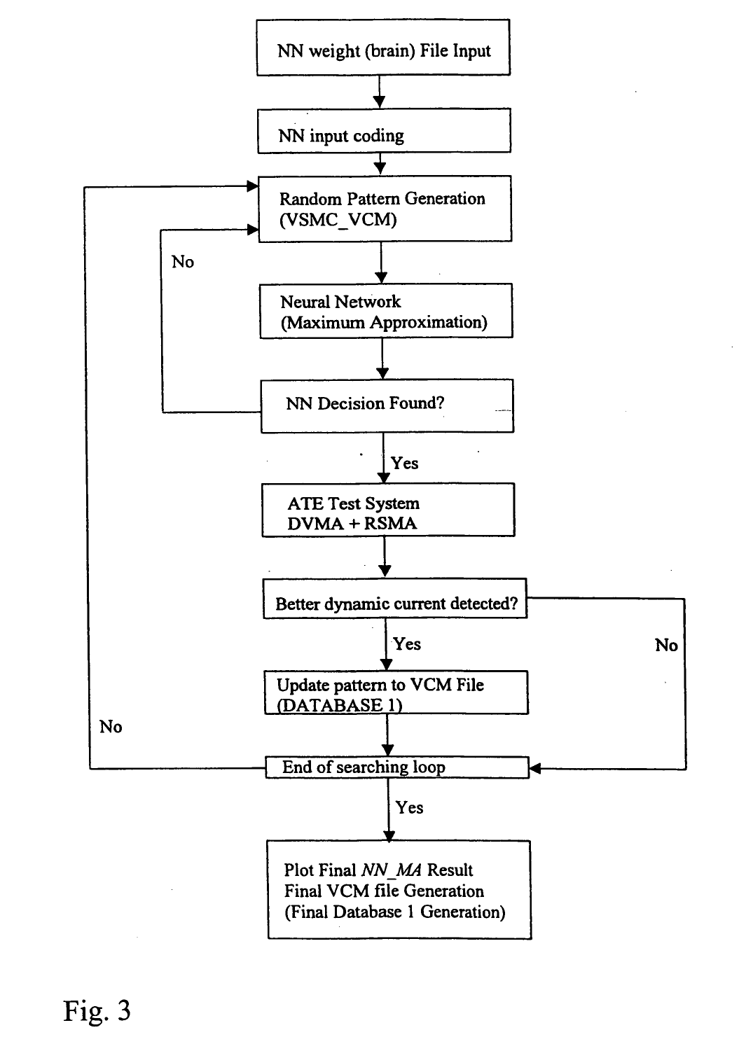

FIG. 3 illustrates a process representing the neural network operation mode according to an embodiment of the invention. In the operation mode, the neural network is able to perform pattern classification based on previous learning experience (contained in the NN brain file) for pattern approximation and selection. The procedure of pattern selection may be based on a very small set of NN pattern populations. For example, one NN pattern population may include six NN decision patterns. The neural network first determines whether any pattern out of these six NN decision patterns belong to a potential maximum current group (sub-optimal group). If yes, then this pattern is selected. If no, then the search is repeated using the same procedure. In the final network classification, only those patterns are selected which cause a higher dynamic current than patterns that have been tested in real measurements (RSMA). For example, using this approach, 6*100=600 patterns can be classified, of which only 100 patterns require testing through measurement to determine if they cause higher dynamic currents, while the other 500 patterns are classified by the neural network.

An implementation of the neural network pattern learning process and the neural network pattern classification process is given in Annex 1 and Annex 2, respectively.

In one embodiment of the invention, the neural network is a back-propagation neural network. Back-propagation is a supervised learning algorithm mainly used by multi-layer-perceptrons in order to change the weights associated with the net's hidden neuron layer(s).

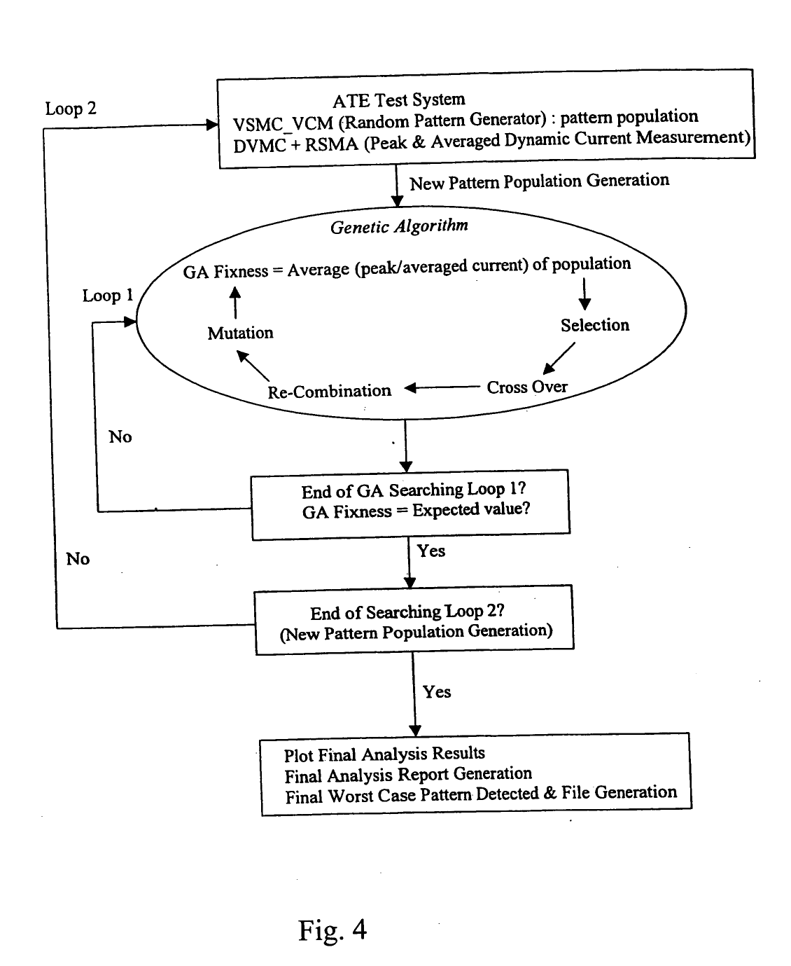

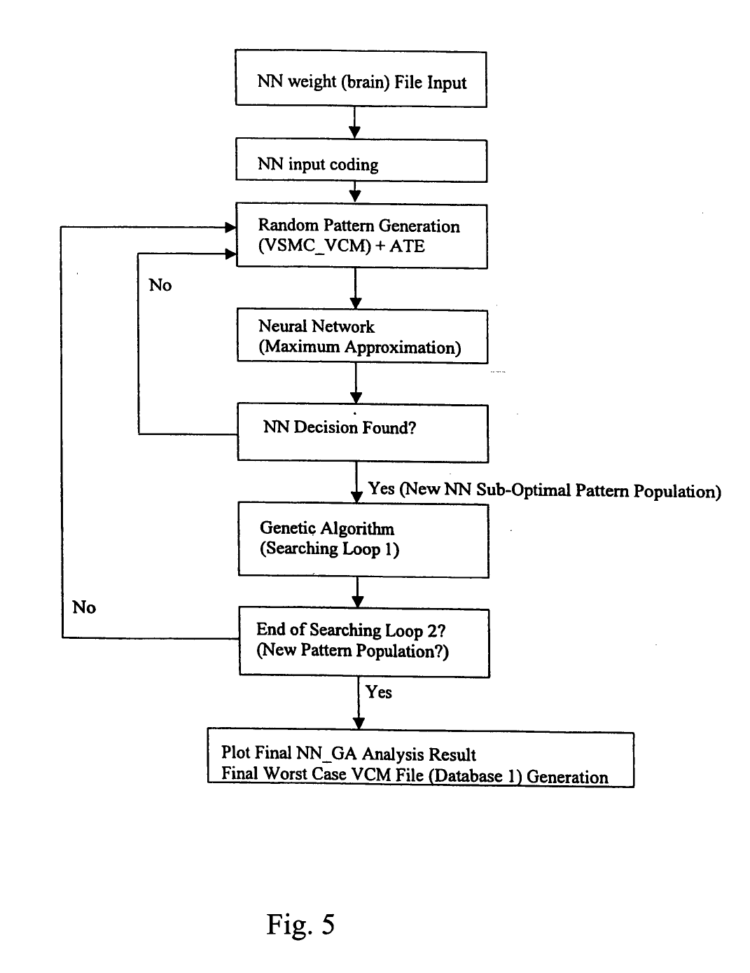

Another embodiment of the invention will now be described by reference to FIGS. 4 and 5. In this embodiment, test patterns selected by the neural network are further optimized using a genetic algorithm.

For the purposes of illustration, FIG. 4 shows a schematic flow diagram of a genetic algorithm without pre-selection of test patterns by a neural network (instead, the initial patterns are generated on a random basis).

FIG. 5 illustrates a schematic flow diagram of a method combining neural network-based pre-selection of test patterns and subsequent optimization using a genetic algorithm, in accordance with an embodiment of the invention.

Genetic algorithms are based on the principles of natural selection. In particular, genetic algorithms are stochastic search methods which simulate natural biological evolution. The algorithms operate on the basis of a population of potential solutions and, applying the principle of “survival of the fittest” to these potential solutions, produce a better approximation of a target solution in each iteration of the algorithm.

Each iteration of the algorithm produces a new generation of approximations. The approximations of each generations are created by the process of selecting individuals according to their level of “fitness” in the problem domain. The selected individuals are bred with one another using operators borrowed from natural genetics. This process leads to the evolution of populations of individuals that are better suited for their environment than the individuals from which they were created, just as in natural adaptation.

Accordingly, genetic algorithms model natural processes such as selection, cross over, recombination and mutation.

FIG. 4 shows a method for detecting the worst case current consumption/peak current pattern (RSMA) based on a genetic algorithm. This method operates on the basis of populations of individual patterns instead of a single pattern solution. In this way, the search for better approximations can be performed in a parallel manner. Therefore, this method is more efficient than single pattern searching processes using dynamic random algorithm methods.

Genetic algorithms may be employed for the simulation of an integrated circuit design in order to solve the worst case pattern search problem. The efficiency of genetic searching procedures is largely dependent on the number of pattern populations and the number of test patterns in each pattern population. However, as indicated above, the simulation-based approach forms a limitation if genetic algorithms are to be employed. The genetic selection procedure has to evaluate every “fitness” (dynamic peak/averaged current) of the test patterns in each pattern population. For example, there may be 200 pattern populations each including 20 patterns. Thus, the genetic algorithm has to evaluate the fitness of 200*20=4,000 patterns. If each test pattern is a 50 cycles test pattern which requires 30 minutes of simulation time (e.g. EPIC or SPICE simulator), then the total required searching and simulation time is 4,000*30 minutes=120,000 minutes, i.e. approximately 83 days of non stop simulation in order to process 200 pattern populations only.

In addition, the full pattern combination domain increases proportionally to the complexity of VLSI (Very Large-Scale Integration) or ULSI (Ultra Large Scale Integration) designs. Therefore, a subset of 200 pattern populations is only a very small subset of the full pattern combination domain.

In contrast, when using a genetic algorithm together with ATE, many more pattern populations per time unit can be processed. This is because the testing of an integrated circuit using ATE is considerably faster than simulation using conventional systems. Accordingly, the approximation of worst case test patterns in a given period of time is much more accurate.

An implementation of a dynamic genetic algorithm for use with ATE is presented in the following. At the beginning of the computation, a number of individual random patterns

P_{N}^{POP}=(p₁,p₂, . . . , p_{N}) (1)

are randomly generated and initialized, wherein N is the maximum number of random patterns and POP is the maximum number of pattern populations.

Subsequently, for each individual pattern (p₁, p₂, . . . , p_{N}), the objective functions

Iₚₑₐₖ(∀Iₛₐₘₚₗₑ(P_{N}, SRMS)) (2)

and

I_{averaged}(P_{N}, SRMS) (3)

are evaluated using equation (4):

$${I}_{Measurement} ( {P}_{N} , T ) = \frac{{V}_{DD} ( {P}_{N} , T )}{{R}_{eff}} + \frac{1}{{L}_{eff}} {\int }_{{T}_{min}}^{{T}_{max}} {V}_{DD} ( {P}_{N} , T ) ⅆ T + Δ {I}_{CMOS} ( {P}_{N} , T ) , ∀ T , {P}_{N} > 0 \\ T = SRMS ( {T}_{min} , {T}_{max} ) ⇒ Random\_Float \_Number ( {T}_{min} , {T}_{max} ) \\ {T}_{max} \geq {T}_{min} , ∀ {T}_{min} , {T}_{max} > 0 , {I}_{Measurement} ( {P}_{N} , T ) ∈ \{ {I}_{peak} {I}_{averaged} \} \qquad ( 4 )$$

The first (initial) generation is thus produced, and the averaged fixness of the individual patterns (p₁, p₂, . . . , p_{N}) is calculated using equation (5):

$$Averaged\_Fixness ( Fixness ( {P}_{N}^{POP} ) ) = \frac{{\sum }_{N = O}^{N} {I}_{Measurement} ( {P}_{N} )}{Fixness ( {P}_{N} ) = {I}_{Measurement}^{N} ( {P}_{N} , T ) ∈ \{ {I}_{peak} {I}_{averaged} \}} , N , {P}_{N} > 0 \qquad ( 5 )$$

If the optimization criteria

$$( Averaged\_Fixness ( {I}_{Measurement} ( {P}_{N}^{POP} ) ) < {I}_{MAX\_REF} ) \qquad ( 6 )$$

is not met for any existing population, a new population is created on the basis of the existing population. Individual patterns are selected according to their fitness for the production of offspring (loop1 in FIG. 4).

In this selection approach, the basic concept of tournament selection is employed. That is, only the best individual pattern from the existing population is selected as a parent. This process is repeated until a pre-defined percentage of best patterns has been selected:

$$Sorting ( {I}_{Measurement} ( {P}_{N} ) ∈ \{ {I}_{min} ( {P}_{{N}_{min}} ) … {I}_{max} ( {P}_{{N}_{max}} ) \} ) ⇒ Parent ( {I}_{Measurement} ( {P}_{N} ) ) \\ N ∈ \{ {N}_{min} {N}_{max} \} N ∈ \{ {N}_{min} = {N}_{max} - ( {N}_{max} \times B ) {N}_{max} \} \qquad ( 7 )$$

wherein B is the pre-defined percentage of the best pattern group. The sorting function first re-arranges the test patterns from minimum to maximum according to their fixness values. Subsequently, the parent selection is generated in random sequence based on the new sub-optimal fixness range N, which is calculated using B. Parents (selected patterns) are combined using cross over (8), re-combined (9) and mutated (10) in order to produce offspring

$$\begin{matrix}CrossOver ( {P}_{N} ( {C}_{1} , {C}_{2} ) , {P}_{N + 1} ( {C}_{3} , {C}_{4} ) ) ⇒ Upper\_CrossOver ( {P}_{N} ( {C}_{3} , {C}_{2} ) , {P}_{N + 1} ( {C}_{1} , {C}_{4} ) ) \\ ⇒ Lower\_CrossOver ( {P}_{N} ( {C}_{1} , {C}_{4} ) , {P}_{N + 1} ( {C}_{3} , {C}_{2} ) ) \\ ⇒ Stripe\_CrossOver ( {P}_{N} ( {C}_{4} , {C}_{3} ) , {P}_{N + 1} ( {C}_{2} , {C}_{1} ) )\end{matrix} \qquad ( 8 )$$

where C is the test pattern content which is selected for cross over of two patterns. In the cross over process, upper, lower or stripe cross over methods are performed in random sequence, and the contents of two cross over patterns are exchanged in order to produce two new offspring patterns.

Thereafter, the re-combination equation (9) is used to select the best fixness pattern out of two new cross over offspring patterns:

ti Recombination (P_{N}, P_{N+1})→Iₘₐₓᵢₘᵤₘ(P_{N}, P_{N+1})→I_{Best}(P_{M}), N, M, P_{N}>0 (9)

$$\begin{matrix}Mutation ( {P}_{M} ( {C}_{1} , {C}_{2} , {C}_{3} , {C}_{4} … {C}_{y} ) ) ⇒ {P}_{M} ( {C}_{1} + {R}_{1} , {C}_{2} + {R}_{2} , … , {C}_{y} + {R}_{y} ) \\ ⇒ {R}_{y} ∈ \{ 1 \; 0 - 1 \} , M , {P}_{M} , y > 0\end{matrix} \qquad ( 10 )$$

where M is the number of new selected offspring patterns to form the new population. After recombination, the offspring undergoes mutation. Offspring variables are mutated by the addition of small random values

Ry∈(1 0 −1) (11)

The mutation process helps to improve the optimization search process.

Finally, all offspring patterns are inserted into the population, replacing the parents (original pattern population) and producing a new generation. This cycle (loop 1 in FIG. 4) is performed until the optimization criteria are met. If the fitness does not improve after a pre-defined number of genetic breeding generations, a new pattern population (loop 2 in FIG. 4) will be generated in random sequence. This combination greatly increases the chances of finding worst case test patterns.

A complete implementation of this algorithm using ATE J973 is given in Annex 3.

FIG. 5 illustrates a flow diagram of a method combining neural network-based pre-selection of test patterns and subsequent optimization using a genetic algorithm.

A complete implementation of this combined approach using ATE J973 is given in Annex 4.

It is to be noted that the invention is not restricted to the embodiments and implementations described herein but encompasses modifications and variations within the scope of the invention as determined from the claims.

Annex 1: Neural Network Pattern Learning Implementation Using ATE J973

Start Neural Network Training Using ATE. Circuit Initialization
Default AC/DC Specification Initialization.
DP Dummy Pattern: Vector Memory Initialization
INPUT. {N Vector_cycle DP Auto_Range ε G Epoch Max_Loop EX File_Name}
Check if Input valid?
else Input Error! exit(1).
For P1 = 0, 1,2,3,...,Auto_Range+1 do : (Automatic Input & Output Range
Calculation)
{
$\begin{matrix}Random\_Pattern \_Generation ⇒ & P ∈ ( {p}_{1} , {p}_{2} , … , {p}_{N} ) : Random Pattern Population \\ & ∀ vector\_cycle , N > 0\end{matrix}$
$\begin{matrix}X ( {P}_{N} , {I}_{peak / averaged} ( {P}_{N} ) ) ∈ \{ {X}_{1} , {X}_{2} … {X}_{i} \} , {X}_{offset} = ( {C}_{max} - {C}_{min} ) \times {R}_{offset} , {R}_{offset} , i > 0 \\ {X}_{1} ∈ \{ {X}_{min} = {X}_{min} + {X}_{offset} \}\end{matrix}$
$\begin{matrix}{X}_{2} ∈ \{ {X}_{mid11} = {X}_{min} - 1 {X}_{mid12} = {X}_{min} + {X}_{offset} \} \\ {X}_{3} ∈ \{ {X}_{mid21} = {X}_{mid12} - 1 {X}_{mid22} = {X}_{mid21} + {X}_{offset} \} \\ {X}_{4} ∈ \{ {X}_{max} = {X}_{mid22} - 1 \}\end{matrix}$
}
Neural Network Training Loop:
{
$\begin{matrix}Random\_Pattern \_Generation ⇒ & P ∈ ( {p}_{1} , {p}_{2} , … , {p}_{N} ) : Random Pattern Population \\ & ∀ vector\_cycle , N > 0\end{matrix}$
$Vector\_Code \_Matrix ( {P}_{N} ( Vector\_Cycles ) ) ⇒ [ \begin{matrix}{P}_{0} ( Vector\_Cycles ) \\ {P}_{1} ( Vector\_Cycles ) \\ ⋮ \\ {P}_{N} ( Vector\_Cycles )\end{matrix} ]$
${P}_{N} ( Vector\_Cycles ) ∈ {P}_{N} ( vector\_encode ( ∀ signal\_bus ) , Vector\_Cycles ) ( ATE Training Set )$
$\begin{matrix}Pattern\_Generator ( Vector\_Memory ( {P}_{N} ) ) \\ ⇒ Pattern\_Controller ( Vector\_Memory ( {P}_{N} ) ) N > 0 ( Pattern Executor )\end{matrix}$
$Start Pattern Generator \text{:} {P}_{N} ( {T}_{min} , {T}_{max} ) ⇒ Dynamic\_Pattern$
Start Current Measurement & Calculation:
$\begin{matrix}{I}_{Measurement} ( {P}_{N} , T ) = \frac{{V}_{DD} ( {P}_{N} , T )}{{R}_{eff}} + \frac{1}{{L}_{eff}} {\int }_{{T}_{min}}^{{T}_{max}} {V}_{DD} ( {P}_{N} , T ) ⅆ T + {ΔI}_{CMOS} ( {P}_{N} , T ) , ∀ T , {P}_{N} > 0 \\ T = SRMS ( {T}_{min} , {T}_{max} ) ⇒ Random\_Float \_Number ( {T}_{min} , {T}_{max} ) \\ {T}_{max} \geq {T}_{min} , ∀ {T}_{min} , {T}_{max} > 0\end{matrix}$
$Stop Pattern Generator \text{:} {P}_{N} : {I}_{peak} ( ∀ {I}_{sample} ( {P}_{N} , SRMS ) ) , {I}_{averaged} ( {P}_{N} , SRMS )$

Z^{k} = I_{Measurement}(P_{N},T)∈{Iₚₑₐₖ I_{averaged}}

${X}^{k} ( {P}_{N} , {I}_{Measurement} ( {P}_{N} ) ) ∈ \{ \begin{matrix}{X}_{1}^{k} & {X}_{2}^{k} & … & {X}_{i}^{k}\end{matrix} \} ( Neural Network Learning Set )$

$\begin{matrix}{X}_{j} = {\sum }_{i} {W}_{ji} {a}_{i} \\ Y ( X ) = \frac{1}{1 + {ⅇ}^{- X \times G}}\end{matrix}$
$\begin{matrix}E = \frac{1}{2} {\sum }_{k = 1}^{s} {\sum }_{j = 1}^{n} {( {Y}_{j}^{k} - {Z}_{j}^{k} )}^{2} ( Supervising Learning via ATE ) \\ \frac{\partial E}{\partial {w}_{ji}} = {\sum }_{k} ( {Y}_{j}^{k} - {Z}_{j}^{k} ) \times {Y}_{j}^{k} ( 1 - {Y}_{j}^{k} ) \times {X}_{i}^{k}\end{matrix}$
$\begin{matrix}{w}_{ji} = {w}_{ji} - ϵ \times ( \frac{\partial E}{\partial {w}_{ij}} ) \times G \\ E ( {P}_{N} ) += E ( {P}_{N} ) ( pattern population Learning Error calculation )\end{matrix}$
Training_Loop++

if (Training_Loop>Epoch) (pattern population learning done)
$\{ E = \frac{\sum E ( {P}_{N} )}{Epoch} \}$
if (Training_Loop>Max_Loop)

{So Far Neural Network Learning File (File_Name) Generation, exit (1)}

If (E>EX)

{Go To Neural Network Training Loop: Learn Again!! Initialize: E=0}

else

{expected Neural Network Learning File (File_Name) Generation, exit(1)}

} End of Neural Network Learning
Final Neural Network Learning Plot Generation
End of Neural Network Learning via ATE

Annex 2: Neural Pattern Classification Implementation Using ATE J973

Start NN_MA: Circuit Initialization
Default AC/DC Specification Initialization.
DP Dummy Pattern: Vector Memory Initialization
INPUT: {N Vector_cycle DP Max_Loop File_Name}
Check if Input valid?
else Input Error! exit(1).
NN_Learning_File (File_Name)∈{ wᵢⱼ ε G X^{k}}
NN_MA_Loop:
{

$\begin{matrix}Random\_Pattern \_Generation ⇒ & P ∈ ( {p}_{1} , {p}_{2} , … , {p}_{N} ) : Random Pattern Population \\ & ∀ vector\_cycle , N > 0\end{matrix}$

${X}^{k} ( {P}_{N} , {I}_{Measurement} ( {P}_{N} ) ) ∈ \{ \begin{matrix}{X}_{1}^{k} & {X}_{2}^{k} & … & {X}_{i}^{k}\end{matrix} \} ( Neural Network Learning Set )$

$\begin{matrix}{X}_{j} = {\sum }_{i} {W}_{ji} {a}_{i} \\ Y ( X ) = \frac{1}{1 + {ⅇ}^{- X \times G}}\end{matrix}$
$if ( ∀ {Y}_{N} ( X ) < {Y}_{sub\_optional \_set} )$
{ Go to NN_MA_Loop : New Pattern Population Generation !!! }
else
$\begin{matrix}\{ Sorting ( {P}_{N} , {Y}_{N} ( X ) ) ⇒ {P}_{M} ( Sub \text{-} optimal set based on \\ neural network ) \}\end{matrix}$

$Vector\_Code \_Matrix ( {P}_{M} ( Vector\_Cycles ) ) ⇒ [ \begin{matrix}{P}_{0} ( Vector\_Cycles ) \\ {P}_{1} ( Vector\_Cycles ) \\ ⋮ \\ {P}_{M} ( Vector\_Cycles )\end{matrix} ]$
P_{M}(Vector_Cycles)∈P_{M}(vector_encode(∀signal_bus), Vector_Cycles))
$\begin{matrix} Pattern\_Generator ( Vector\_Memory ( {P}_{M} ) ) \\ ⇒ Pattern\_Controller ( Vector\_Memory ( {P}_{M} ) ) M > 0 ( Pattern Executor )\end{matrix}$
$Start Pattern Generator \text{:} {P}_{M} ( {T}_{min} , {T}_{max} ) ⇒ Dynamic\_Pattern$
Start Current Measurement & Calculation:
${I}_{Measurement} ( {P}_{M} , T ) = \frac{{V}_{DD} ( {P}_{M} , T )}{{R}_{eff}} + \frac{1}{{L}_{eff}} {\int }_{{T}_{min}}^{{T}_{max}} {V}_{DD} ( {P}_{M} , T ) ⅆ T + {ΔI}_{CMOS} ( {P}_{M} , T ) , ∀ T , {P}_{M} > 0$

$\begin{matrix}T = SRMS ( {T}_{min} , {T}_{max} ) ⇒ Random\_Float \_Number ( {T}_{min} , {T}_{max} ) \\ {T}_{max} \geq {T}_{min} , ∀ {T}_{min} , {T}_{max} > 0\end{matrix}$

Stop Pattern Generator: P_{M} : Iₚₑₐₖ(∀Iₛₐₘₚₗₑ(P_{M},SRMS)), I_{averaged}(P_{M},SRMS)

I_{Measurement}(P_{M},T)∈{Iₚₑₐₖ I_{averaged}}

NN_Max_Loop++(operating loop counted)
$Sorting ( {P}_{M} , {I}_{Measuremet} ( {P}_{M} ) ) ⇒ {P}_{selscted} ( best out of sub \text{-} optimal set via ATE )$
if(I_{Measurement}(P_{selected})>∀I_{Measurement}(Pₚᵣₑᵥᵢₒᵤₛ_{_{—}}selected))

{ Update VCM Database File }

if(NN_Max_Loop<Max_Loop)

{ Go to NN_MA_Loop : New Pattern Population Generation!!! }

else

{ Final VCM Database File Generation exit(1)}

}
Final Neural Network Maximum Approximation Plot Generation.
End of NN_MA

Annex 3: Dynamic Genetic Algorithm Implementation Using ATE J973

Start D_GA: Circuit Initialization
Default AC/DC Specification Initialization.
DP Dummy Pattern: Vector Memory Initialization
INPUT: {N Vector_Cycles DP Loop1 Loop2 I_{Max}_{_{—}}Ref}
Check if Input valid?
else Input Error! exit(1).
For POP = 0,1,2,3,...,Loop2+1 do:

{

$\begin{matrix}Random\_Pattern \_Generation ⇒ P ∈ ( {p}_{1} , {p}_{2} , … , {p}_{N} ) \\ ∀ vector\_cycle , N > 0 \\ {P}_{N}^{POP} = ( {p}_{1} , {p}_{2} , … {p}_{N} ) Initial Pattern Population\end{matrix}$
For P1=0, 1, 2, 3, ..., N+1 do:

{

$Vector\_Code \_Matrix ( {P}_{N} ( Vector\_Cycles ) ) ⇒ [ \begin{matrix}{P}_{0} ( Vector\_Cycles ) \\ {P}_{1} ( Vector\_Cycles ) \\ ⋮ \\ {P}_{N} ( Vector\_Cycles )\end{matrix} ]$
${P}_{N} ( Vector\_Cycles ) ∈ {P}_{N} ( vector\_encode ( ∀ signal\_bus ) , Vector\_Cycles )$
$\begin{matrix}Pattern\_Generator ( Vector\_Memory ( {P}_{N} ) ) \\ ⇒ Pattern\_Controller ( Vector\_Memory ( {P}_{N} ) ) N > 0 ( Pattern Executor )\end{matrix}$
$Start Pattern Generator \text{:} {P}_{N} ( {T}_{min} , {T}_{max} ) ⇒ Dynamic\_Pattern$
Start Current Measurement & Calculation:
${I}_{Measurement} ( {P}_{N} , T ) = \frac{{V}_{DD} ( {P}_{N} , T )}{{R}_{eff}} + \frac{1}{{L}_{eff}} {\int }_{{T}_{min}}^{{T}_{max}} {V}_{DD} ( {P}_{N} , T ) ⅆ T + {ΔI}_{CMOS} ( {P}_{N} , T ) , ∀ T , {P}_{N} > 0$

$\begin{matrix}T = SRMS ( {T}_{min} , {T}_{max} ) ⇒ Random\_Float \_Number ( {T}_{min} , {T}_{max} ) \\ {T}_{max} \geq {T}_{min} , ∀ {T}_{min} , {T}_{max} > 0\end{matrix}$

Stop Pattern Generator: P_{N} : Iₚₑₐₖ(∀Iₛₐₘₚₗₑ(P_{N},SRMS)), I_{averaged}(P_{N}, SRMS)

Fixness (P_{N}) = I_{Measurement} (P_{N}, T)∈{Iₚₑₐₖ I_{averaged}}

}

$Averaged\_Fixness ( Fixness ( {P}_{N}^{POP} ) ) = \frac{{\sum }_{N = 0}^{N} {I}_{Measurement} ( {P}_{N} )}{N} , N , {P}_{N} > 0$
$if ( Averaged\_Fixness ( {I}_{Measurement} ( {P}_{N}^{POP} ) ) > {I}_{Max\_Ref} )$

{Final VCM Generation (Database 1) exit (1) }

For P2 = 0, 1, 2, 3, . . . Loopl+1 do:

{

$\begin{matrix}Sorting ( {I}_{Meaurement} ( {P}_{N} ) ∈ \{ {I}_{min} ( {P}_{{N}_{min}} ) … {I}_{max} ( {P}_{{N}_{max}} ) \} ) & ⇒ Parent ( {I}_{Measurment} ( {P}_{N} ) ) \\ N ∈ \{ {N}_{min} {N}_{max} \} & N ∈ \{ {N}_{min} = {N}_{max} - ( {N}_{max} \times B ) {N}_{max} \}\end{matrix}$
$\begin{matrix}CrossOver ( {P}_{N} ( {C}_{1} , {C}_{2} ) , {P}_{N + 1} ( {C}_{3} , {C}_{4} ) ) ⇒ Upper\_CrossOver ( {P}_{N} ( {C}_{3} , {C}_{2} ) , {P}_{N + 1} ( {C}_{1} , {C}_{4} ) ) \\ ⇒ Lower\_CrossOver ( {P}_{N} ( {C}_{1} , {C}_{4} ) , {P}_{N + 1} ( {C}_{3} , {C}_{2} ) ) \\ ⇒ Stripe\_CrossOver ( {P}_{N} ( {C}_{4} , {C}_{3} ) , {P}_{N + 1} ( {C}_{2} , {C}_{1} ) )\end{matrix}$
$Recombination ( {P}_{N} , {P}_{N + 1} ) ⇒ {I}_{maximum} ( {P}_{N} , {P}_{N + 1} ) ⇒ {I}_{Best} ( {P}_{M} ) , N , M , {P}_{N} > 0$
$\begin{matrix}Mutation ( {P}_{M} ( {C}_{1} , {C}_{2} , {C}_{3} , {C}_{4} … {C}_{y} ) ) ⇒ {P}_{M} ( {C}_{1} + {R}_{1} , {C}_{2} + {R}_{2} , … {C}_{y} + {R}_{y} ) \\ ⇒ {R}_{y} ∈ \{ 1 \; 0 - 1 \} , M , {P}_{M} , y > 0\end{matrix}$
For P3 =0,1,2,3,..., M+1 do:

{

$\begin{matrix} Pattern\_Generator ( Vector\_Memory ( {P}_{M} ) ) \\ ⇒ Pattern\_Controller ( Vector\_Memory ( {P}_{M} ) ) M > 0 ( Pattern Executor )\end{matrix}$
$Start Pattern Generator \text{:} {P}_{M} ( {T}_{min} , {T}_{max} ) ⇒ Dynamic\_Pattern$
Current Measurement & Calculation:
${I}_{Measurement} ( {P}_{M} , T ) = \frac{{V}_{DD} ( {P}_{M} , T )}{{R}_{eff}} + \frac{1}{{L}_{eff}} {\int }_{{T}_{min}}^{{T}_{max}} {V}_{DD} ( {P}_{M} , T ) ⅆ T + {ΔI}_{CMOS} ( {P}_{M} , T ) , ∀ T , {P}_{M} > 0$

$\begin{matrix}T = SRMS ( {T}_{min} , {T}_{max} ) ⇒ Random\_Float \_Number ( {T}_{min} , {T}_{max} ) \\ {T}_{max} \geq {T}_{min} , ∀ {T}_{min} , {T}_{max} > 0\end{matrix}$

Stop Pattern Generator: P_{M} : Iₚₑₐₖ(∀Iₛₐₘₚₗₑ(P_{M}, SRMS)), I_{averaged}(P_{M},SRMS)

Fixness (P_{M})=I_{Measurement}(P_{M},T)∈{Iₚₑₐₖ I_{averaged}}

{

$Averaged\_Fixness ( Fixness ( {P}_{M}^{POP} ) ) = \frac{{\sum }_{M = 0}^{M} {I}_{Measurement} ( {P}_{M} )}{M} , M , {P}_{M} > 0$
$if ( Averaged\_Fixness ( {I}_{Measurement} ( {P}_{M}^{POP} ) ) > {I}_{Max\_Ref} )$

{Worst Case Pattern Found : Final VCM Generation(Database 1)exit(1)}
} End Of Loop 1

} End of Loop 2
Update So Far Worst Case Pattern Found : Final VCM Generation (Database 1)
End of D_GA

Annex 4: Combined Neural Network Pattern Classification and Dynamic Genetic
Algorithm Implementation Using ATE J973

Start NN GA. Circuit Initialization
Default AC/DC Specification Initialization.
DP Dummy Pattern: Vector Memory Initialization
INPUT. {N Vector_cycle DP Max_Loop Loop1 I_{Max}_{_{—}}REF File_Name}
Check if Input valid?
else Input Error! exit(1).
NN_Learning File (File_Name)∈{wᵢⱼ ε G X^{k}}
NN_GA_Loop:

{

$\begin{matrix}Random\_Pattern \_Generation ⇒ & P ∈ ( {p}_{1} , {p}_{2} , … , {p}_{N} ) : Random Pattern Population \\ & ∀ vector\_cycle , N > 0\end{matrix}$
${X}^{k} ( {P}_{N} , {I}_{Measurement} ( {P}_{N} ) ) ∈ \{ \begin{matrix}{X}_{1}^{k} & {X}_{2}^{k} & … & {X}_{i}^{k}\end{matrix} \} ( Neural Network Learning Set$

$\begin{matrix}{X}_{j} = {\sum }_{i} {W}_{ji} {a}_{i} \\ {Y}_{N} ( X ) = \frac{1}{1 + {ⅇ}^{- X \times G}}\end{matrix}$
$if ( ∀ {Y}_{N} ( X ) < {Y}_{sub\_optimal \_set} )$
{ Go to NN_MA_Loop: New Pattern Population Generation!!! }
else
$\begin{matrix}Sorting ( {P}_{N} {Y}_{N} ( X ) ) ⇒ {P}_{M} ( sub \text{-} optimal set based on neural network ) \\ {P}_{M} ⇒ {P}_{N} ( replacing the old population with new sub \text{-} optimal set )\end{matrix}$

For P1 = 0,1,2,3,..., Loop1+ 1 do : (Start genetic algorithm to further improve sub-
optimal set)

{

$\begin{matrix}Sorting ( {I}_{Meaurement} ( {P}_{N} ) ∈ \{ {I}_{min} ( {P}_{{N}_{min}} ) … {I}_{max} ( {P}_{{N}_{max}} ) \} ) ⇒ Parent ( {I}_{Measurment} ( {P}_{N} ) ) \\ N ∈ \{ {N}_{min} {N}_{max} \} \\ N ∈ \{ {N}_{min} = {N}_{max} - ( {N}_{max} \times B ) {N}_{max} \}\end{matrix}$
$\begin{matrix}CrossOver ( {P}_{N} ( {C}_{1} , {C}_{2} ) , {P}_{N + 1} ( {C}_{3} , {C}_{4} ) ) ⇒ Upper\_CrossOver ( {P}_{N} ( {C}_{3} , {C}_{2} ) , {P}_{N + 1} ( {C}_{1} , {C}_{4} ) ) \\ ⇒ Lower\_CrossOver ( {P}_{N} ( {C}_{1} , {C}_{4} ) , {P}_{N + 1} ( {C}_{3} , {C}_{2} ) ) \\ ⇒ Stripe\_CrossOver ( {P}_{N} ( {C}_{4} , {C}_{3} ) , {P}_{N + 1} ( {C}_{2} , {C}_{1} ) )\end{matrix}$
$Recombination ( {P}_{N} , {P}_{N + 1} ) ⇒ {I}_{maximum} ( {P}_{N} , {P}_{N + 1} ) ⇒ {I}_{Best} ( {P}_{M} ) , N , M , {P}_{N} > 0$
$\begin{matrix}Mutation ( {P}_{M} ( {C}_{1} , {C}_{2} , {C}_{3} , {C}_{4} … {C}_{y} ) ) ⇒ {P}_{M} ( {C}_{1} + {R}_{1} , {C}_{2} + {R}_{2} , … {C}_{y} + {R}_{y} ) \\ ⇒ {R}_{y} ∈ \{ 1 \; 0 - 1 \} , M , {P}_{M} , y > 0\end{matrix}$
For P3 =0,1,2,3,..., M+1 do:

{

$\begin{matrix} Pattern\_Generator ( Vector\_Memory ( {P}_{M} ) ) \\ ⇒ Pattern\_Controller ( Vector\_Memory ( {P}_{M} ) ) M > 0 ( Pattern Executor )\end{matrix}$
$Start Pattern Generator \text{:} {P}_{M} ( {T}_{min} , {T}_{max} ) ⇒ Dynamic\_Pattern$
Current Measurement & Calculation:
${I}_{Measurement} ( {P}_{M} , T ) = \frac{{V}_{DD} ( {P}_{M} , T )}{{R}_{eff}} + \frac{1}{{L}_{eff}} {\int }_{{T}_{min}}^{{T}_{max}} {V}_{DD} ( {P}_{M} , T ) ⅆ T + {ΔI}_{CMOS} ( {P}_{M} , T ) , ∀ T , {P}_{M} > 0$

$\begin{matrix}T = SRMS ( {T}_{min} , {T}_{max} ) ⇒ Random\_Float \_Number ( {T}_{min} , {T}_{max} ) \\ {T}_{max} \geq {T}_{min} , ∀ {T}_{min} , {T}_{max} > 0\end{matrix}$

Stop Pattern Generator: P_{M} : Iₚₑₐₖ(∀Iₛₐₘₚₗₑ(P_{M},SRMS), I_{averaged} (P_{M}, SRMS)

Fixness (P_{M}) = I_{Measurement} (P_{M},T)∈{Iₚₑₐₖ I_{averaged}}

{
$\begin{matrix}Averaged\_Fixness ( Fixness ( {P}_{M}^{POP} ) ) = \frac{{\sum }_{M = 0}^{M} {I}_{Measurement} ( {P}_{M} )}{M} , M , {P}_{M} > 0 \\ if ( Averaged\_Fixness ( {I}_{Measurement} ( {P}_{M}^{POP} ) ) > {I}_{Max\_Ref} )\end{matrix}$

{Worst Case Pattern Found : Final VCM Generation (Database 1) exit(1)}
{ End of Loop 1

NN_Max_Loop++ (operatiang loop counter)
if (NN_Max_Loop > Max_Loop)

{ Go to NN_GA_Loop: New Pattern Population Generation!!!)

else
{So Far Worst Case Pattern Found : Final VCM Generation (Database 1) exit(1)}
}
Final Neural Network_+ GA Plot Generation (Fig. 31)
End of NN+GA

We claim:

1. A method of approximating a behavior of an integrated circuit, the method which comprises the steps of:
(a) applying a set of test patterns to a system for one of testing and simulating an integrated circuit;
(b) applying the set of test patterns to a neural network;
(c) comparing outputs of the system for one testing and simulating the integrated circuit and outputs of the neural network for providing a comparison result; and
(d) adapting parameters of the neural network to approximate a behavior of the integrated circuit based the comparison result.

2. The method according to claim 1, which comprises:
using, as the system for one of testing and simulating the integrated circuit, an automatic test equipment (ATE); and
applying the set of test patterns to the integrated circuit via the automatic test equipment.

3. The method according to claim 2, which comprises implementing the neural network in the automatic test equipment.

4. The method according to claim 1, which comprises generating the set of test patterns on a random basis.

5. The method according to claim 1, wherein step (d) includes adapting inter-unit weights of the neural network through back-propagation.

6. The method according to claim 1, which comprises repeating steps (a) to (d) until a level of adaptation in step (d) falls below a given value.

7. The method according to claim 5, which comprises storing data representing predetermined neural network parameters after terminating a repetition of steps (a) to (d).

8. A method of selecting test patterns, the method which comprises the steps of:
(a) approximating a behavior of an integrated circuit by applying a set of test patterns to a system for one of testing and simulating the integrated circuit, applying the set of test patterns to a neural network, comparing outputs of the system for one testing and simulating the integrated circuit and outputs of the neural network for providing a comparison result, and adapting parameters of the neural network in order to approximate the behavior of the integrated circuit based the comparison result;
(b) applying a test pattern to the neural network whose parameters have been adapted to approximate the behavior of the integrated circuit in accordance with step (a);
(c) processing an output of the neural network to determine whether given criteria are met; and
(d) selecting the test pattern for storage if the given criteria are met.

9. The method according to claim 8, which comprises repeating steps (b) to (d) until a given number of test patterns have been stored.

10. The method according to claim 8, which comprises concluding that the given criteria are met if a value of a given parameter of a signal output by the neural network in response to applying the test pattern exceeds a reference value.

11. The method according to claim 10, which comprises:
(e) applying a further set of test patterns to the integrated circuit by using an automatic test equipment;
(f) measuring values of the given parameter of output signals generated by the integrated circuit in response to step (e); and
(g) concluding that the given criteria are met if the value of the given parameter of the signal output by the neural network in response to applying a test pattern exceeds the reference value and all values measured in step (f).

12. The method according to claim 11, which comprises generating the further set of test patterns on a random basis.

13. The method according to claim 10, which comprises using a dynamic current as the given parameter.

14. The method according to claim 8, which further comprises:
(h) generating a test pattern population formed of a plurality of test patterns;
(i) applying each test pattern of the test pattern population to the neural network;
(j) processing, for each test pattern, the output of the neural network to determine a value of a given parameter; and
(k) allocating each test pattern to one of a plurality of classification groups in accordance with the value of the given parameter determined in step (j).

15. The method according to claim 14, which comprises repeating steps (h) to (k) using a new test pattern population formed of test patterns included in a selected one of the classification groups.

16. The method according to claim 15, which comprises using, as the selected one of the classification groups, test patterns that approximate a set of worst case input parameters of operation of the integrated circuit.

17. The method according to claim 8, which comprises:
repeating steps (b) to (d) a number of times;
applying the test patterns selected in each step (d) to a simulator for simulating the integrated circuit;
processing an output of the simulator to determine whether further given criteria are met; and
selecting for storage those test patterns that meet the further given criteria.

18. The method according to claim 8, which comprises:
repeating steps (b) to (d) a number of times;
applying test patterns selected in each repetition of step (d) to the integrated circuit by using an automatic test equipment;
processing an output of the automatic test equipment to determine whether further given criteria are met; and
selecting for storage those test patterns which meet the further given criteria.

19. The method according to claim 8, which comprises using, as the given criteria, a representation of an approximation of a worst case mode of operation of the integrated circuit.

20. A method of simulating an integrated circuit, the method which comprises the steps of:
selecting test patterns by, in a first step, applying a test pattern to a neural network whose parameters have been adapted to approximate a behavior of an integrated circuit by applying a set of test patterns to a system for one of testing and simulating the integrated circuit, applying the set of test patterns to a neural network, and comparing outputs of the system for one of testing and simulating the integrated circuit and outputs of the neural network, and, in a second step, processing an output of the neural network to determine whether given criteria are met and selecting a test pattern if the given criteria are met; and
applying test patterns that have been selected to a simulator for simulating the integrated circuit.

21. A method of testing an integrated circuit, the method which comprises the steps of:
selecting test patterns by, in a first step, applying a test pattern to a neural network whose parameters have been adapted to approximate a behavior of an integrated circuit by applying a set of test patterns to a system for one of testing and simulating the integrated circuit, applying the set of test patterns to a neural network, and comparing outputs of the system for one of testing and simulating the integrated circuit and outputs of the neural network, and, in a second step, processing an output of the neural network to determine whether given criteria are met and selecting a test pattern if the given criteria are met; and
applying test patterns that have been selected to the integrated circuit by using an automatic test equipment.

22. A method of providing a test pattern for one of a simulation and a test of a layout of an integrated circuit, the method which comprises the steps of:
(A) providing a set of test patterns that have been selected by, in a first step, applying a test pattern to a neural network whose parameters have been adapted to approximate a behavior of an integrated circuit by applying a set of test patterns to a system for one of testing and simulating an integrated circuit, applying the set of test patterns to a neural network, and comparing outputs of the system for one of testing and simulating the integrated circuit and outputs of the neural network, and, in a second step, processing an output of the neural network to determine whether given criteria are met and selecting a test pattern if the given criteria are met; and
(B) applying the set of test patterns to the integrated circuit by using an automatic test equipment (ATE);
(C) determining outputs of the integrated circuit;
(D) processing the outputs to determine whether given test criteria are met; and
(E) depending on a determination in step (D), generating a new set of test patterns based on the set of test patterns provided by step (A) by using a genetic algorithm.

23. The method according to claim 22, which comprising repeating steps (B) to (E) until the given test criteria are met.

24. The method according to claim 22, which comprises repeating steps (B) to (E) until a condition is met, the condition being selected from the group consisting of meeting the given test criteria and repeating steps (B) to (E) a given number of times.

25. The method according to claim 22, which comprises concluding that the given test criteria are met if the set of test patterns is associated with an average fitness above a given value.

26. The method according to claim 22, wherein step (E) includes combining at least some of the test patterns according to the genetic algorithm in order to provide the new set of test patterns.

27. The method according to claim 26, which further comprises:
selecting test patterns from the set of test patterns according to given selection criteria in order to provide selected test patterns; and
combining the selected test patterns according to the genetic algorithm to provide the new set of test patterns.

28. The method according to claim 27, which comprises selecting a test pattern if the test pattern is associated with a fitness value greater than a reference value.

29. The method according to claim 27, which comprises selecting a test pattern if the test pattern is associated with a highest fitness value of all unselected test patterns.

30. The method according to claim 27, which comprises selecting a test pattern if the test pattern is associated with a highest fitness value of all unselected test patterns, and repeating the selecting step until a given percentage of test patterns has been selected.

31. The method according to claim 29, wherein step (E) includes:
(F) sorting selected test patterns according to an order of associated fitness values;
(G) randomly selecting parent test patterns from test patterns as sorted in step (F); and
(H) combining selected ones of the parent test patterns.

32. The method according to claim 22, which comprises using at least one element selected from the group consisting a mutation, a crossing over, and a re-combination for the genetic algorithm.

33. The method according to claim 22, wherein the step (A) includes providing a plurality of sets of test patterns such that each of the sets of test patterns is included in a test pattern population.

34. The method according to claim 22, which comprises providing a plurality of test pattern populations and performing steps (B) to (E) for each of the test pattern populations.

35. A data processing configuration, comprising:
a system for one of testing and simulating an integrated circuit, said system being configured to be supplied with a set of test patterns;
a neural network operatively connected to said system for one of testing and simulating the integrated circuit, said neural network being configured to be provided with the set of test patterns;
a comparison unit operatively connected to said neural network and said system for one of testing and simulating the integrated circuit, said comparison unit being configured to compare outputs from said system for one of testing and simulating the integrated circuit and from said neural network in order to provide a comparison result; and
an adapting unit operatively connected to said comparison unit, said adapting unit being configured to adapt parameters of said neural network in order to approximate a behavior of the integrated circuit based the comparison result.

36. A computer-readable medium having computer-executable instructions for performing a method which comprises the steps of:
applying a set of test patterns to a system for one of testing and simulating an integrated circuit;
applying the set of test patterns to a neural network;
comparing outputs of the system for one of testing and simulating the integrated circuit and outputs of the neural network for providing a comparison result; and
adapting parameters of the neural network to approximate a behavior of the integrated circuit based the comparison result.
